(19) United States
(12) Patent Application Publication
(10) Pub. No.: US 2026/0332183 A1
(43) Pub. Date: Oct. 22, 2026

(54) RADIO FREQUENCY MODULE, COMMUNICATION DEVICE, AND CONTROL METHOD

(71) Applicant: Murata Manufacturing Co, Ltd., Nagaokakyo-shi (JP)

(72) Inventors: Kenji TAHARA, Nagaokakyo-shi (JP); Kae YAMAMOTO, Nagaokakyo-shi (JP)

(21) Appl. No.: 19/703,164

(22) Filed: Jun. 10, 2026

Related U.S. Application Data
(63) Continuation of application No. PCT/JP2025/002236, filed on Jan. 24, 2025.

(30) Foreign Application Priority Data
Feb. 5, 2024 (JP) 2024-015368

(51) Int. Cl. H04B 1/40; H04B 1/00

(52) U.S. Cl. CPC H04B 1/40; H04B 1/006; H04B 1/0078

(57) ABSTRACT

In the radio frequency module that switches the transmission and reception circuits using the switch, the low-noise amplifier is connected to the main line of the Marchand balun with the line (the fifth line) and the switch connected to the line (the fifth line) is in the conducting state in transmission to convert the impedance when the reception circuit is viewed from the antenna into an open state. With this configuration, the supply of the signal in a transmission frequency band to the reception circuit is capable of being suppressed. Accordingly, it is possible to improve the isolation characteristics between the transmission and reception circuits.

### CROSS REFERENCE TO RELATED APPLICATION

This is a continuation of International Application No. PCT/JP2025/002236 filed on Jan. 24, 2025 which claims priority from Japanese Patent Application No. 2024-015368 filed on Feb. 5, 2024. The contents of these applications are incorporated herein by reference in their entireties.

### BACKGROUND OF THE DISCLOSURE

### Field of the Disclosure

The present disclosure generally relates to a radio frequency module, a communication device including the radio frequency module, and a control method. More particularly, the present disclosure relates to a technique to improve isolation between transmission and reception circuits.

### Description of the Related Art

In electronic devices capable of transmitting and receiving radio frequency radio waves, an electronic device separately having a transmission antenna and a reception antenna and an electronic device having a transmission-reception antenna are known.

U.S. Pat. No. 10,715,204 discloses an electronic device having the transmission-reception antenna. A power amplifier for transmission and a low-noise amplifier for reception are provided for the transmission-reception antenna in U.S. Pat. No. 10,715,204, and a transmission circuit and a reception circuit are switched using a switch.

### BRIEF SUMMARY OF THE DISCLOSURE

When transmission coupling and reception coupling are switched using a switch in a magnetically coupled transformer described in U.S. Pat. No. 10,715,204, the switch made of semiconductor is generally used. In this case, part of the radio frequency radio waves may pass through the switch due to parasitic capacitance that inevitably occurs in the switch even when the switch is in a non-conducting state and isolation characteristics between the transmission circuit and the reception circuit may be reduced to cause noise.

In order to resolve the above problem, it is a possible benefit of the present disclosure is to improve the isolation characteristics between transmission and reception circuits in a radio frequency module that performs transmission and reception of a radio frequency signal using an antenna.

A radio frequency module according to the present disclosure includes a first terminal through which a transmission signal passes, a second terminal through which a reception signal passes, a third terminal through which a transmission signal and a reception signal pass, a converter that outputs a first transmission signal and a second transmission signal having a phase opposite to that of the first transmission signal based on the transmission signal that has passed through the first terminal, a first amplifier that amplifies each of the first transmission signal and the second transmission signal, a second amplifier that amplifies a reception signal to output the amplified reception signal to the second terminal, a first line having one end into which the first transmission signal amplified by the first amplifier is inputted and the other end that is grounded, a second line having one end into which the second transmission signal amplified by the first amplifier is inputted and the other end that is grounded, a third line that has one end connected to the third terminal and that is arranged side by side with the first line, a fourth line that has one end connected to the other end of the third line and that is arranged side by side with the second line, a fifth line having one end connected to the other end of the fourth line and the other end connected to an input terminal of the second amplifier, and a first switch provided between the other end of the fifth line and the ground.

A control method according to the present disclosure is a control method used for a radio frequency module. The radio frequency module includes a first terminal through which a transmission signal passes, a second terminal through which a reception signal passes, a third terminal through which a transmission signal and a reception signal pass, a converter that outputs a first transmission signal and a second transmission signal having a phase opposite to that of the first transmission signal based on the transmission signal that has passed through the first terminal, a first amplifier that amplifies each of the first transmission signal and the second transmission signal, a second amplifier that amplifies a reception signal to output the amplified reception signal to the second terminal, a first line having one end into which the first transmission signal amplified by the first amplifier is inputted and the other end that is grounded, a second line having one end into which the second transmission signal amplified by the first amplifier is inputted and the other end that is grounded, a third line that has one end connected to the third terminal and that is arranged side by side with the first line, a fourth line that has one end connected to the other end of the third line and that is arranged side by side with the second line, a fifth line having one end connected to the other end of the fourth line and the other end connected to an input terminal of the second amplifier, and a first switch provided between the other end of the fifth line and the ground. The control method includes setting the first switch to a non-conducting state in reception of radio waves and setting the first switch to a conducting state in transmission of radio waves.

A radio frequency module according to an aspect includes a first terminal through which a transmission signal passes, a second terminal through which a reception signal passes, a third terminal through which a transmission signal and a reception signal pass, a converter that outputs a first transmission signal and a second transmission signal having a phase opposite to that of the first transmission signal based on the transmission signal that has passed through the first terminal, a first amplifier that amplifies each of the first transmission signal and the second transmission signal, a second amplifier that amplifies a reception signal to output the amplified reception signal to the second terminal, a first line having one end into which the first transmission signal amplified by the first amplifier is inputted and the other end that is grounded, a second line having one end into which the second transmission signal amplified by the first amplifier is inputted and the other end that is grounded, a third line that has one end connected to the third terminal and that is electromagnetically coupled to the first line, a fourth line that has one end connected to the other end of the third line and that is electromagnetically coupled to the second line, a fifth line having one end connected to the other end of the fourth line and the other end connected to an input terminal of the second amplifier, and a first switch provided between the other end of the fifth line and the ground.

According to the present disclosure, in the radio frequency module that switches the transmission and reception circuits using the switch, the low-noise amplifier is connected to the main line of the Marchand balun with the line (the fifth line) and the switch connected to the line (the fifth line) is in the conducting state in transmission to convert the impedance when the reception circuit is viewed from the antenna into an open state. With this configuration, the supply of the signal in a transmission frequency band to the reception circuit is capable of being suppressed. Accordingly, it is possible to improve the isolation characteristics between the transmission and reception circuits.

### BRIEF DESCRIPTION OF THE SEVERAL VIEWS OF THE DRAWINGS

FIG. 1 is a diagram illustrating a schematic configuration of a communication device in a first embodiment.

FIG. 2 is a circuit diagram illustrating a detailed configuration of a power amplifier in the first embodiment.

FIG. 3 is a graph for describing bandpass characteristics of a balun in transmission.

FIG. 4 is a graph for describing characteristics of a low pass filter composed of a capacitor and a line.

FIG. 5 is a plan view illustrating the balun and the line in the first embodiment.

FIG. 6 is a circuit diagram illustrating a detailed configuration of a power amplifier in a comparative example.

FIG. 7 is a diagram illustrating a flowchart of a process performed in a control circuit in the first embodiment.

FIG. 8 is a circuit diagram illustrating a detailed configuration of a power amplifier in a second embodiment.

FIG. 9 is a graph indicating insertion loss of an LC parallel resonant circuit composed of a capacitor and a line in the second embodiment.

FIG. 10 is a diagram illustrating a flowchart of a process performed in the control circuit in the second embodiment.

FIG. 11 is a circuit diagram illustrating a detailed configuration of a power amplifier in a third embodiment.

FIG. 12 is a graph indicating the insertion loss of the LC parallel resonant circuit composed of the capacitor and the line in the third embodiment.

FIG. 13 is a circuit diagram illustrating a detailed configuration of a power amplifier in a modification.

### DETAILED DESCRIPTION OF THE DISCLOSURE

Embodiments of the present disclosure will herein be described in detail with reference to the drawings. The same reference numerals and letters are added in the drawings to identify the same components or equivalent components and description of such components is not repeated.

### First Embodiment

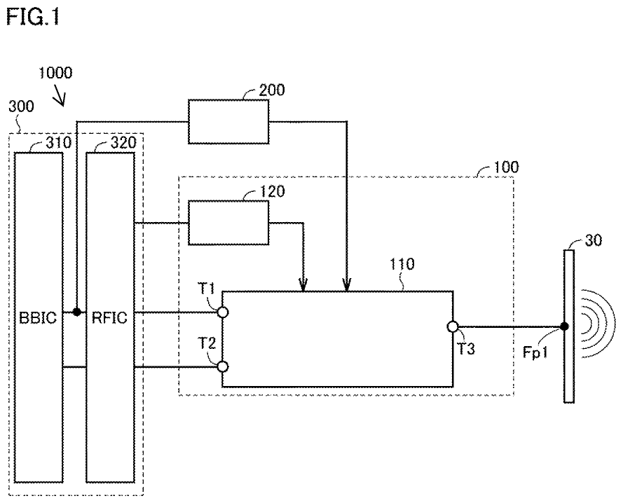

A schematic configuration of a radio frequency module 100 and a communication device 1000 in a first embodiment will be described with reference to FIG. 1. FIG. 1 is a diagram illustrating the schematic configuration of the communication device 1000 in the first embodiment.

### Entire Configuration

The circuit configuration of the communication device 1000 will now be described. The communication device 1000 is a device used in a communication system and is, for example, a smartphone, a mobile terminal such as a tablet, a personal computer having a communication function, or the like. As illustrated in FIG. 1, the communication device 1000 in the first embodiment includes the radio frequency module 100, a power supply circuit 200, a signal processing circuit 300, and an antenna 30.

The radio frequency module 100 is connected to the antenna 30 through which radio waves are transmitted and received. The signal processing circuit 300 includes a baseband integrated circuit (BBIC) 310 composing a baseband signal processing circuit and a radio frequency integrated circuit (RFIC) 320.

The radio frequency module 100 includes a control circuit 120 and a power amplifier 110. The radio frequency module 100 supplies a radio frequency (RF) signal from the RFIC 320 to the antenna 30 and from the antenna 30 to the RFIC 320. The RFIC 320 processes the radio frequency signal transmitted to and received from the power amplifier 110.

The RFIC 320 converts an intermediate frequency (IF) signal inputted from the BBIC 310 into the radio frequency signal (a transmission signal) through up-conversion to supply the generated radio frequency signal to a connection terminal T1 of the power amplifier 110. The power amplifier 110 amplifies the transmission signal supplied from the RFIC 320 to output the amplified transmission signal to the antenna 30 via a connection terminal T3. The antenna 30 transmits the transmission signal inputted from the connection terminal T3 as the radio waves.

The radio frequency signal (a reception signal) received through the antenna 30 is amplified by the power amplifier 110 with low noise and then, is supplied to the RFIC 320 through a connection terminal T2. The RFIC 320 converts the reception signal amplified by the power amplifier 110 with low noise into an IF signal through down-conversion to output the generated IF signal to the BBIC 310.

In the communication device 1000 of the first embodiment, a transmission frequency band is a band from 120 GHz to 140 GHz. In other words, the center frequency of the transmission frequency band is 130 GHz. In an aspect, the transmission band of the communication device 1000 may be another band. For example, the transmission band of the communication device 1000 may be a band from 130 GHz to 150 GHz or a band from 140 GHz to 160 GHz.

The power supply circuit 200 generates power supply voltage based on transmission information from the BBIC 310. The generated power supply voltage is supplied to a switch, amplifiers, and so on described below, which are included in the power amplifier 110. The control circuit 120 controls the switch, the amplifiers, and so on described below, which are included in the power amplifier 110, based on a control signal outputted from the RFIC 320. Part of the function or the entire function as the control circuit 120 may be installed in the signal processing circuit 300.

### Circuit Configuration

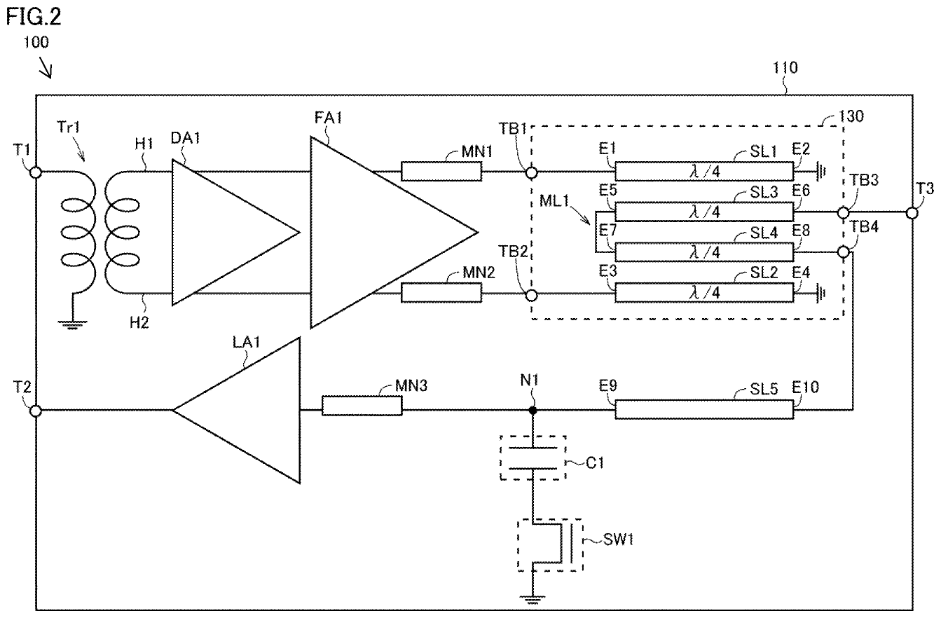

FIG. 2 is a circuit diagram illustrating a detailed configuration of the power amplifier 110 in the first embodiment. Referring to FIG. 2, the power amplifier 110 includes the connection terminals T1 to T3, a transformer Tr1, a driver amplifier DA1, a power amplifier FA1, a balun 130, a low-noise amplifier LA1, a line SL5, a capacitor C1, a switch SW1, and matching circuits MN1 to MN3.

The components (the transformer Tr1, the driver amplifier DA1, the power amplifier FA1, the matching circuits MN1 and MN2, and the balun 130), which are included in the power amplifier 110 along a signal path of the power amplifier 110 in transmission, will now be described. The transmission signal outputted from the RFIC 320 to the power amplifier 110 is inputted into one end of a primary winding of the transformer Tr1 via the connection terminal T1. The other end of the primary winding of the transformer Tr1 is connected to a ground electrode (reference potential).

The transformer Tr1 converts the transmission signal inputted into the connection terminal T1 into two signals having opposite phases. More specifically, the transmission signal inputted into the connection terminal T1 is converted into a transmission signal that is inputted from an end portion H1 of a secondary winding into the driver amplifier DA1 and a transmission signal that is inputted from an end portion H2 of the secondary winding into the driver amplifier DA1. In other words, differential signals are inputted into the driver amplifier DA1 from the end portion H1 and the end portion H2.

The power amplifier 110 of the first embodiment includes the driver amplifier DA1 at a driver stage and the power amplifier FA1 at an output stage. The driver amplifier DA1 and the power amplifier FA1 amplify the differential signals. Although one amplifier is illustrated as the driver amplifier DA1 in FIG. 2, the driver amplifier DA1 may be composed of multipole amplifiers. Specifically, for example, the power amplifier 110 may separately include an amplifier that amplifies the transmission signal inputted from the end portion H1 and an amplifier that amplifies the transmission signal inputted from the end portion H2 as the driver amplifier DA1. Similarly, the power amplifier FA1 may also be composed of multiple amplifiers.

The matching circuit MN1 is provided between the power amplifier FA1 and the balun 130 and performs impedance matching between the power amplifier FA1 and the balun 130. The radio frequency signal subjected to the matching in the matching circuit MN1 is supplied to a balanced terminal TB1 of the balun 130. Similarly, the matching circuit MN2 is also provided between the power amplifier FA1 and the balun 130 and performs impedance matching between the power amplifier FA1 and the balun 130. The radio frequency signal subjected to the matching in the matching circuit MN2 is supplied to a balanced terminal TB2 of the balun 130.

The balun 130 includes a pair of the balanced terminals TB1 and TB2, an unbalanced terminal TB3, a connection terminal TB4, lines SL1 and SL2, and a main line ML1. The main line ML1 has a configuration in which a line SL3 is connected in series to a line SL4. When the wavelength of the radio frequency signal that is to be transmitted is denoted by λ, each of the lines SL1 to SL4 has an electrical length of λ/4. In other words, the main line ML1 has an electrical length of λ/2.

In the first embodiment, the balun 130 converts balanced signals (the differential signals) inputted into the balanced terminal TB1 and the balanced terminal TB2 into an unbalanced signal to output the unbalanced signal from the unbalanced terminal TB3. The balun 130 is capable of being used to convert the unbalanced signal inputted into the unbalanced terminal TB3 into the balanced signals to output the balanced signals from the balanced terminal TB1 and the balanced terminal TB2.

The balun 130 is a so-called Marchand balun in which the two lines: the line SL1 and the line SL2 having a length of λ/4 are coupled to the main line ML1 having a length (λ/2) of a half of the wavelength λ, which is connected to the unbalanced terminal TB3. In such a Marchand balun, the lengths of the main line ML1 and the lines SL1 to SL4 are appropriately set in accordance with the center frequency (130 GHz) of the pass band of the balun 130.

As illustrated in FIG. 2, an end portion E1 of the line SL1 is connected to the balanced terminal TB1. An end portion E2 of the line SL1 is connected to ground potential. Similarly, an end portion E3 of the line SL2 is connected to the balanced terminal TB2. An end portion E4 of the line SL2 is also connected to the ground potential.

An end portion E6 of the line SL3 included in the main line ML1 is connected to the unbalanced terminal TB3. An end portion E5 of the line SL3 is connected to an end portion E7 of the line SL4. An end portion E8 of the line SL4 included in the main line ML1 is connected to the connection terminal TB4.

The line SL1, which is a balanced line, and the line SL3 of the main line ML1, which is an unbalanced line, are arranged side by side. The line SL1 is electromagnetically coupled to the line SL3. Similarly, the line SL2, which is a balanced line, and the line SL4 of the main line ML1, which is an unbalanced line, are arranged side by side. The line SL2 is electromagnetically coupled to the line SL4. As described above, the phase of the radio frequency signal inputted into the line SL1 via the balanced terminal TB1 is opposite to the phase of the radio frequency signal inputted into the line SL2 via the balanced terminal TB2. The respective transmission signals outputted to the unbalanced terminal TB3 have the same phase due to the electromagnetic coupling between the lines SL1 and SL3 and the electromagnetic coupling between the lines SL2 and SL4.

In the Marchand balun having the above configuration, the balanced signals (the differential signals) inputted into the balanced terminal TB1 (an input terminal) and the balanced terminal TB2 (the input terminal) are supplied to the main line ML1 through the electromagnetic coupling and are outputted from the unbalanced terminal TB3 (an output terminal) as the unbalanced signal. The unbalanced signal outputted from the unbalanced terminal TB3 is supplied to the antenna 30 via the connection terminal T3.

The components (the line SL5, the matching circuit MN3, the low-noise amplifier LA1, the capacitor C1, and the switch SW1), which are included in the power amplifier 110 along a signal path of the power amplifier 110 in reception, will now be described. The reception signal received through the antenna 30 is supplied to the unbalanced terminal TB3 of the balun 130 via the connection terminal T3. The reception signal is supplied to the connection terminal TB4 through the main line ML1.

An end portion E10 of the line SL5 is connected to the connection terminal TB4. The line SL5 has an electrical length of, for example, less than λ/4. The matching circuit MN3 is connected to an end portion E9 of the line SL5. The matching circuit MN3 is provided between the low-noise amplifier LA1 and the end portion E9 of the line SL5 and performs impedance matching between the low-noise amplifier LA1 and the line SL5. The reception signal subjected to the matching in the matching circuit MN3 is supplied to an input terminal of the low-noise amplifier LA1.

The low-noise amplifier LA1 is connected between the connection terminal T2 and the matching circuit MN3. The low-noise amplifier LA1 amplifies the reception signal with low noise and then, outputs the amplified reception signal to the connection terminal T2. In addition, in the first embodiment, the capacitor C1 is connected to the end portion E9 of the line SL5, as illustrated in FIG. 2. One end of the switch SW1 is connected to the capacitor C1. The other end of the switch SW1 is connected to the ground electrode.

In the first embodiment, the control circuit 120 controls the switch SW1 so as to be in a conducting state in transmission in which the radio waves are transmitted by the communication device 1000 and controls the switch SW1 so as to be in a non-conducting state in reception in which the radio waves are received. In the first embodiment, the electrical length of the line SL5 and the capacitance value of the capacitor C1 are adjusted so that the impedance when the input terminal of the low-noise amplifier LA1 is viewed from the connection terminal TB4 is in an open state when the switch SW1 is controlled so as to be in the conducting state in transmission of the radio waves.

More specifically, an inductive component of the line SL5 is connected in series between the input terminal of the low-noise amplifier LA1 and the connection terminal TB4. Accordingly, the inductive component of the line SL5 rotates the impedance clockwise on a Smith chart. A capacitance component of the capacitor C1 is provided on a shunt path between the input terminal of the low-noise amplifier LA1 and the connection terminal TB4. The capacitance component of the capacitor C1 also rotates the impedance clockwise on the Smith chart. When the switch SW1 that is grounded is controlled so as to be in the conducting state, the impedance between the switch SW1 and the capacitor C1 is in a short state. In the first embodiment, the electrical length of the line SL5 and the capacitance value of the capacitor C1 are adjusted so as to rotate the impedance by 180 degrees on the Smith chart.

More specifically, since the length of the line SL5 is less than λ/4 in the first embodiment, the line SL5 rotates the impedance by less than 180 degrees on the Smith chart. The capacitance value of the capacitor C1 of the first embodiment is adjusted, along with the line SL5, so as to rotate the impedance by 180 degrees on the Smith chart. Accordingly, the impedance when the input terminal of the low-noise amplifier LA1 is viewed from the connection terminal TB4 is in the open state. In other words, the transmission signal is inhibited from being supplied to the line SL5 to improve isolation characteristics between the transmission and reception circuits.

The length of the line SL5 may be λ/4 or more. For example, when the line SL5 has a length of λ/4, the impedance on the Smith chart is capable of being rotated by 180 degrees only by the arrangement of the line SL5 to set the impedance when the input terminal of the low-noise amplifier LA1 is viewed from the connection terminal TB4 to the open state. In this case, the power amplifier 110 does not include the capacitor C1 but includes only the switch SW1 on the shunt path.

When the length of the line SL5 exceeds λ/4, the impedance on the Smith chart rotates by a degree greater than 180 degrees due to the arrangement of the line SL5. In this case, the power amplifier 110 includes a component to rotate the impedance on the Smith chart counterclockwise. The component to rotate the impedance counterclockwise may be a capacitor connected in series between the input terminal of the low-noise amplifier LA1 and the connection terminal TB4, an inductor provided on the shunt path between the input terminal of the low-noise amplifier LA1 and the connection terminal TB4, or the like.

As described below, the connection order of the switch SW1 and the capacitor C1 may be reversed. In the first embodiment, the capacitor C1 is arranged between the path on which the reception signal passes and the switch SW1. With this configuration, in the first embodiment, it is possible to suppress the degree of influence of the switch SW1 on the reception circuit.

### Bandpass Characteristics

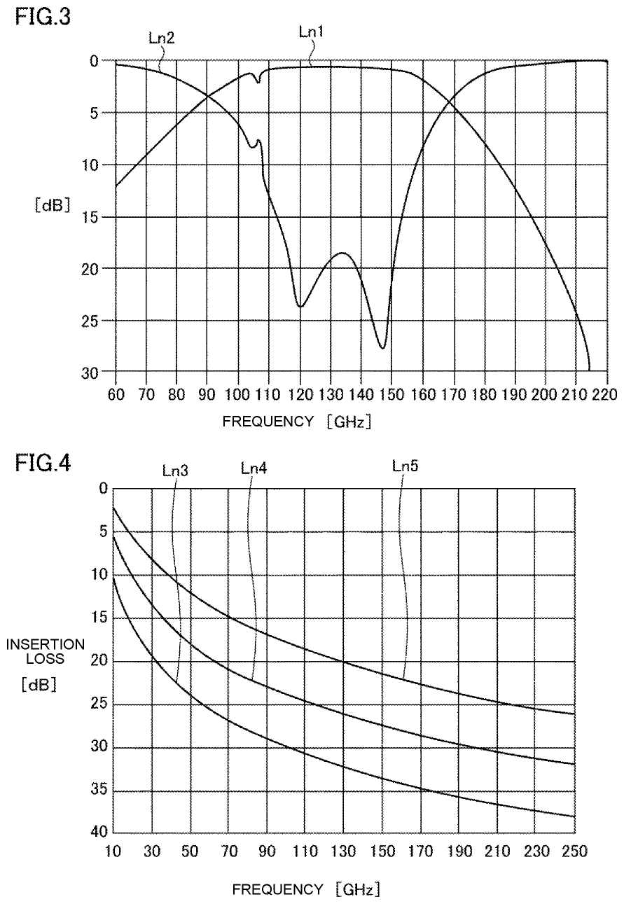

FIG. 3 is a graph for describing bandpass characteristics of the balun 130 in transmission. Referring to FIG. 3, the horizontal axis represents frequency and the vertical axis represents insertion loss and return loss of the balun 130. A line Ln1 indicates the insertion loss of the balun 130 in transmission. A line Ln2 indicates the return loss of the balun 130 in transmission.

At a frequency of 120 GHz, the insertion loss of the balun 130 is 0.5 dB and the return loss of the balun 130 is 23.4 dB. At a frequency of 130 GHz, the insertion loss of the balun 130 is 0.6 dB and the return loss of the balun 130 is 19.2 dB. At a frequency of 140 GHz, the insertion loss of the balun 130 is 0.7 dB and the return loss of the balun 130 is 20.5 dB.

As indicated in FIG. 3, controlling the switch SW1 so as to be in the conducting state sets the impedance when the input terminal of the low-noise amplifier LA1 is viewed from the connection terminal TB4 to the open state, thus reducing the insertion loss in transmission. In other words, the radio frequency module 100 of the first embodiment is capable of improving the isolation characteristics between the transmission and reception circuits.

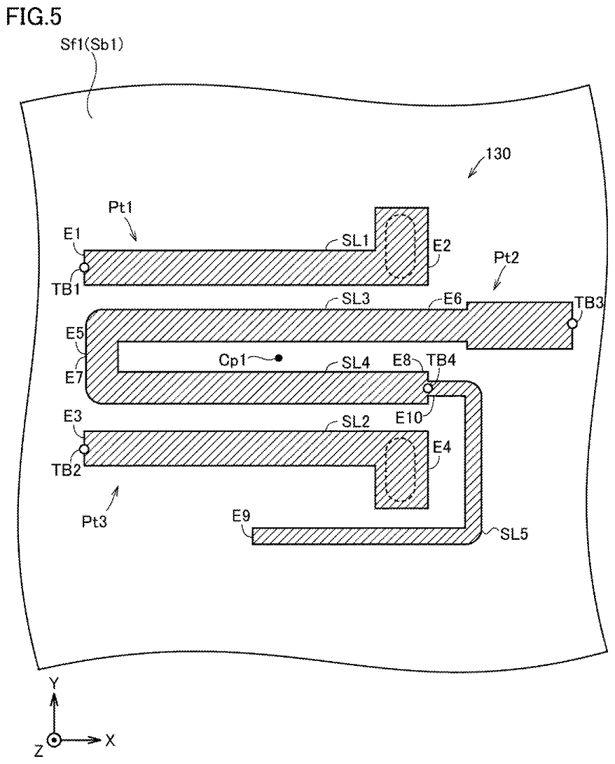

Referring back to FIG. 2, in the radio frequency module 100 of the first embodiment, when the switch SW1 is in the conducting state, the capacitance component of the capacitor C1 and the inductive component of the line SL5 compose a low pass filter. FIG. 4 is a graph for describing characteristics of the low pass filter composed of the capacitor C1 and the line SL5.

Referring to FIG. 4, the horizontal axis represents frequency and the vertical axis represents the insertion loss of the low pass filter composed of the capacitor C1 and the line SL5. A line Ln3 indicates the insertion loss of the low pass filter when the capacitance value of the capacitor C1 is 2,000 fF. A line Ln4 indicates the insertion loss of the low pass filter when the capacitance value of the capacitor C1 is 1,000 fF. A line Ln5 indicates the insertion loss of the low pass filter when the capacitance value of the capacitor C1 is 500 fF.

As indicated by the line Ln3, the insertion loss at a frequency of 130 GHz is 20 dB. As indicated by the line Ln4, the insertion loss at a frequency of 130 GHz is 26 dB. As indicated by the line Ln5, the insertion loss at a frequency of 130 GHz is 32 dB. The insertion loss of the low pass filter is increased as the frequency to be transmitted is increased regardless of the capacitance value of the capacitor C1. As described above, in the radio frequency module 100 of the first embodiment, the supply of the transmission signal to the line SL5 is suppressed with the increasing frequency band of the transmission signal. Accordingly, in the communication device in the first embodiment and so on, it is possible to further improve the isolation characteristics between the transmission and reception circuits. In addition, in the radio frequency module 100 of the first embodiment, it is also possible to suppress the influence of a jamming signal and the like in a frequency band higher than the transmission frequency band.

### External View

FIG. 5 is a plan view illustrating the balun 130 and the line SL5 in the first embodiment. As illustrated in FIG. 5, the balun 130 and the line SL5 are formed on a dielectric substrate Sb1. Referring to FIG. 5, the normal direction of a main surface Sf1 of the dielectric substrate Sb1 is the Z axis, a certain direction inside the main surface Sf1 is the X axis, and the direction orthogonal to the X axis is the Y axis. The dielectric substrate Sb1 of the first embodiment is a substrate in which multiple layers are laminated. In an aspect, the dielectric substrate Sb1 may be a single-layer substrate.

The lines SL1 and SL2, the main line ML1, and the line SL5, which are included in the balun 130, are formed on the main surface Sf1 of the dielectric substrate Sb1. As illustrated in FIG. 5, a wiring pattern Pt1, a wiring pattern Pt2, and a wiring pattern Pt3 are formed on the main surface Sf1.

In the first embodiment, the line SL1 described with reference to FIG. 2 is realized by the wiring pattern Pt1 illustrated in FIG. 5. The wiring pattern Pt1 includes the end portions E1 and E2. The balanced terminal TB1 is connected to the end portion E1 of the wiring pattern Pt1. Similarly, the line SL4 described with reference to FIG. 2 is realized by the wiring pattern Pt3 illustrated in FIG. 5. The wiring pattern Pt3 includes the end portions E3 and E4. The balanced terminal TB2 is connected to the end portion E3 of the wiring pattern Pt3.

The main line ML1 described with reference to FIG. 2 is realized by the wiring pattern Pt2 illustrated in FIG. 3. The wiring pattern Pt2 is connected to the unbalanced terminal TB3. As illustrated in FIG. 3, the main line ML1 extends to the negative direction side of the X-axis direction from the end portion E6 and winds counterclockwise around the Z axis passing through a point Cp1, which is used as the winding axis. In other words, the main line ML1 has a shape that is wound around the Z axis passing through the point Cp1 in a plan view of the dielectric substrate Sb1.

A portion from the end portion E6 to the end portion E5 in the wiring pattern Pt2 corresponds to the line SL3. A portion from the end portion E7 to the end portion E8 in the wiring pattern Pt2 corresponds to the line SL4. A portion from the end portion E6 to the end portion E8 has a length of λ/2. The end portion E8 is connected to the line SL5. A portion from the end portion E10 to the end portion E9 in the wiring pattern Pt2 corresponds to the line SL5.

As illustrated in FIG. 5, the line SL1 and the line SL3 are arranged side by side. More specifically, the line SL1 and the line SL3 are arranged so as to extend along the X-axis direction. The line SL1 is electromagnetically coupled to the line SL3. Similarly, the line SL2 and the line SL4 are arranged side by side. More specifically, the line SL2 and the line SL4 are arranged so as to extend along the X-axis direction. The line SL2 is electromagnetically coupled to the line SL4.

### Comparative Example

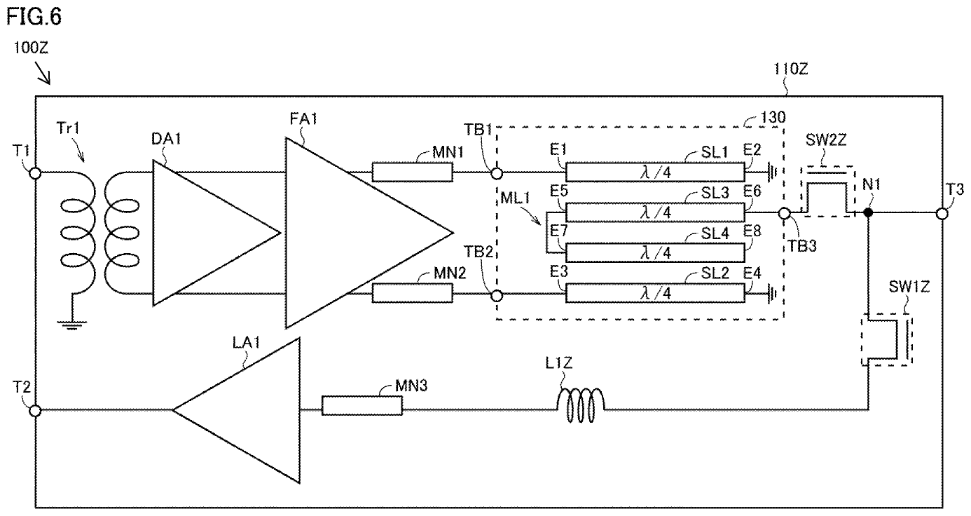

FIG. 6 is a circuit diagram illustrating a detailed configuration of a power amplifier 110Z in a comparative example. A radio frequency module 100Z of the comparative example differs from the radio frequency module 100 of the first embodiment in that, in addition to the matching circuit MN3, an inductor L1Z and a switch SW1Z are connected in series between the input terminal of the low-noise amplifier LA1 and the connection terminal T3. In addition, in the radio frequency module 100Z, a switch SW2Z is connected between the connection terminal T3 and the unbalanced terminal TB3. As illustrated in FIG. 6, the switch SW1Z is provided between the inductor L1Z and a connection node N1 and the switch SW2Z is provided between the unbalanced terminal TB3 and the connection node N1.

In the configuration of the comparative example, when the transmission circuit and the reception circuit are switched by controlling the conducting states of the switches SW1Z and SW2Z, part of the transmission signal may pass through the switch SW1Z even if the switch SW1Z is in the non-conducting state due to parasitic capacitance of the switch SW1Z to reduce the isolation between the transmission and reception circuits. In the first embodiment, since impedance conversion is performed by the line SL5 and the capacitor C1, the impedance when the input terminal of the low-noise amplifier LA1 is viewed from the connection terminal TB4 is capable of being set to the open state. As described above, it is possible to switch the transmission and reception circuits while suppressing the reduction in isolation between the transmission and reception circuits in the first embodiment, compared with the comparative example.

In the radio frequency module 100Z of the comparative example, since it is necessary to ensure an area to separately provide the inductor L1Z at the reception side, the size of the radio frequency module 100Z is increased. As described above with reference to FIG. 2, in the radio frequency module 100 of the first embodiment, it is possible to achieve the impedance matching in a state in which the main line ML1 is shared between transmission and reception. As a result, in the radio frequency module 100 of the first embodiment, it is not necessary to separately provide the inductor L1Z.

In addition, in the radio frequency module 100Z of the comparative example, the reception signal passes through the switch SW1Z to be supplied from the connection terminal T3 to the connection terminal T2 when the switch SW1Z is in the conducting state and the switch SW2Z is in the non-conducting state. In other words, in the comparative example, the switch SW1Z is arranged on a supply path of the reception signal. Accordingly, in the comparative example, loss occurs at the switch SW1Z in supply of the reception signal. Similarly, in the radio frequency module 100Z of the comparative example, when the switch SW2Z is in the conducting state and the switch SW1Z is in the non-conducting state, the transmission signal inputted from the connection terminal T1 passes through the switch SW2Z to be supplied to the connection terminal T3. In other words, in the comparative example, loss occurs at the switch SW2Z in supply of the transmission signal. In contrast, in the first embodiment, since the switch SW1 is not arranged on the supply paths of the reception signal and the transmission signal, it is possible to suppress the occurrence of the loss due to the switch SW1 in supply of the signal.

### Processing in Control Circuit 120

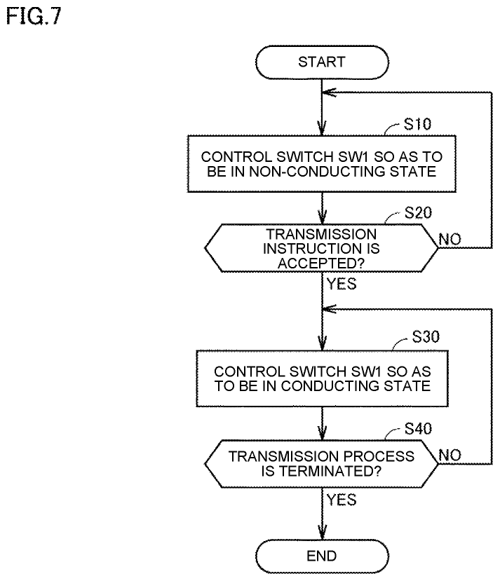

FIG. 7 is a diagram illustrating a flowchart of a process performed in the control circuit 120 in the first embodiment. The flowchart illustrated in FIG. 7 is stored in a storage unit included in the communication device 1000 as a program and is realized by the program that is executed by a processing circuit, such as a central processing unit (CPU), included in the control circuit 120. The flowchart illustrated in FIG. 7 is repeatedly performed at certain timings.

The control circuit 120 controls the switch SW1 so as to be in the non-conducting state (Step S10). The state of the communication device 1000 is controlled so as to be in a reception mode. The control circuit 120 determines whether a transmission instruction is accepted (Step S20). The transmission instruction is transmitted from the CPU or the like in the communication device 1000 to the control circuit 120. If the transmission instruction is not accepted (NO in Step S20), the control circuit 120 returns the process to Step S10.

If the transmission instruction is accepted (YES in Step S20), the control circuit 120 controls the switch SW1 so as to be in the conducting state (Step S30). The state of the radio frequency module 100 is controlled so as to be in a transmission mode. Then, the control circuit 120 determines whether a transmission process is terminated (Step S40). If the transmission process is not terminated (NO in Step S40), the control circuit 120 keeps the conducting state of the switch SW1 (Step S30).

If the transmission process is terminated (YES in Step S40), the control circuit 120 terminates the process in the flowchart and, after a predetermined time period, starts the flowchart again. Accordingly, in the communication device 1000 of the first embodiment, it is possible to control the state of the communication device 1000 so as to be in the transmission mode when data is transmitted and to control the state of the communication device 1000 so as to be in the reception mode when no data is transmitted. Although the example is described above in which the transmission mode and the reception mode are switched based on whether the transmission instruction is accepted, the transmission mode and the reception mode may be switched based on elapse of a predetermined time period.

The connection terminals T1, T2, and T3 may correspond to a “first terminal”, a “second terminal”, and a “third terminal”, respectively, in the present disclosure. The lines SL1 to SL5 may correspond to a “first line” to a “fifth line”, respectively, in the present disclosure. The transmission signal inputted from the end portion H1 into the balanced terminal TB1 may correspond to a “first transmission signal” in the present disclosure. The transmission signal inputted from the end portion H2 into the balanced terminal TB2 may correspond to a “second transmission signal” in the present disclosure. The switch SW1 may correspond to a “first switch” in the present disclosure. The capacitor C1 may correspond to a “first capacitor” in the present disclosure. The transformer Tr1 may correspond to a “converter” in the present disclosure. The power amplifier FA1 may correspond to a “first amplifier” in the present disclosure. The low-noise amplifier LA1 may correspond to a “second amplifier” in the present disclosure.

The end portion E1 may correspond to “one end of the first line”. The end portion E2 may correspond to the “other end of the first line”. The end portion E3 may correspond to “one end of the second line”. The end portion E4 may correspond to the “other end of the second line”. The end portion E5 may correspond to the “other end of the third line”. The end portion E6 may correspond to “one end of the third line”. The end portion E7 may correspond to “one end of the fourth line”. The end portion E8 may correspond to the “other end of the fourth line”. The end portion E9 may correspond to the “other end of the fifth line”. The end portion E10 may correspond to “one end of the fifth line”.

### Second Embodiment

In a second embodiment, an example of a configuration further including a parallel resonator in the first embodiment will be described. Description of the components duplicated with those in the first embodiment is not repeated in the second embodiment.

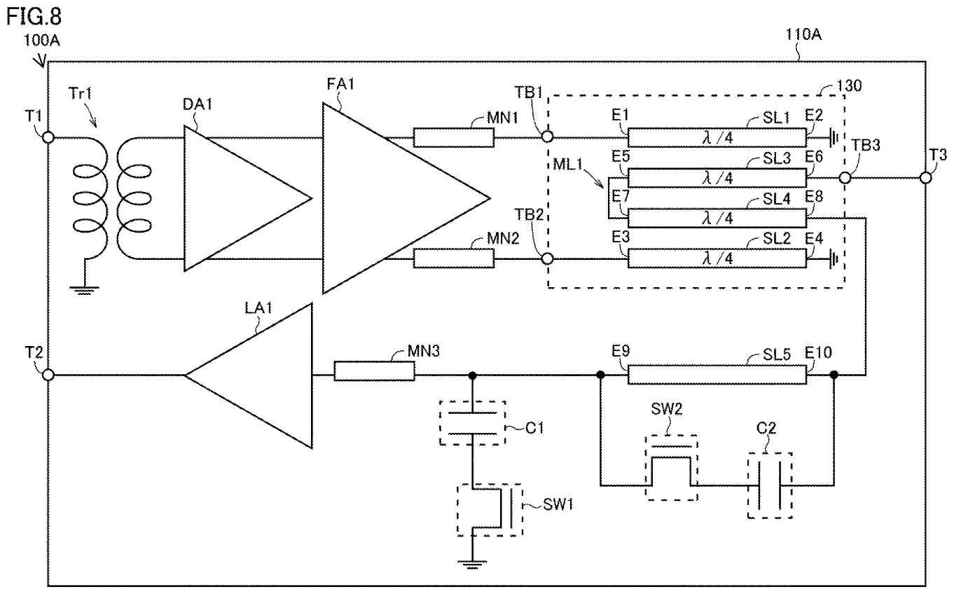

FIG. 8 is a circuit diagram illustrating a detailed configuration of a power amplifier 110A in the second embodiment. In a radio frequency module 100A in the second embodiment, a switch SW2 and a capacitor C2 that are connected in parallel to the line SL5 are arranged.

More specifically, the capacitor C2 and the switch SW2 are connected in series between the end portion E9 and the end portion E10 of the line SL5. In other words, the capacitor C2 and the switch SW2, which are connected in series to each other, are connected in parallel to the line SL5. The connection order of the capacitor C2 and the switch SW2, which are connected in series to each other, may be reversed with respect to the example illustrated in FIG. 8. In the example in the second embodiment, when the switch SW2 is in the conducting state, the capacitor C2 and the line SL5 compose an LC parallel resonant circuit.

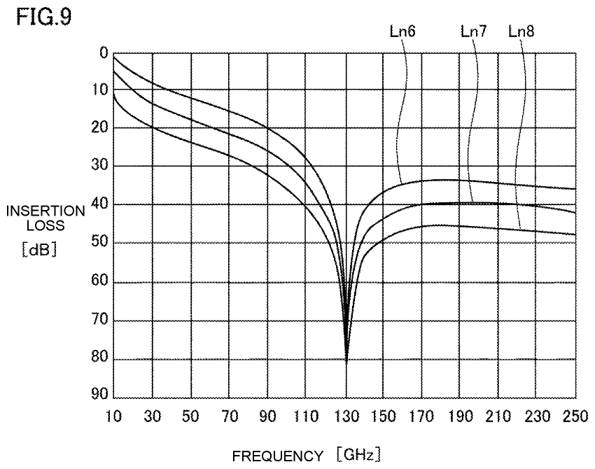

FIG. 9 is a graph for describing the insertion loss of the LC parallel resonant circuit composed of the capacitor C2 and the line SL5 in the second embodiment. The insertion loss from the connection terminal TB4 to the input terminal of the low-noise amplifier LA1 is indicated in FIG. 9. FIG. 9 indicates that passing of the transmission signal is blocked by both the LC parallel resonant circuit in the second embodiment and the low pass filter in the first embodiment. A line Ln6 indicates the insertion loss when the capacitance value of the capacitor C2 is 500 fF. A line Ln7 indicates the insertion loss when the capacitance value of the capacitor C2 is 1,000 fF. A line Ln8 indicates the insertion loss when the capacitance value of the capacitor C2 is 2,000 fF.

As illustrated in FIG. 9, in the LC parallel resonant circuit, the inductance of the line SL5 and the capacitance value of the capacitor C2 are set so that an attenuation pole is generated near 130 GHz. Accordingly, the transmission signal passing through the main line ML1 illustrated in FIG. 8 is inhibited from being supplied to the input terminal of the low-noise amplifier LA1 due to the LC parallel resonant circuit. In other words, in the second embodiment, the isolation between the power amplifier FA1 and the low-noise amplifier LA1 is further ensured due to the LC parallel resonant circuit composed of the capacitor C2 and the line SL5.

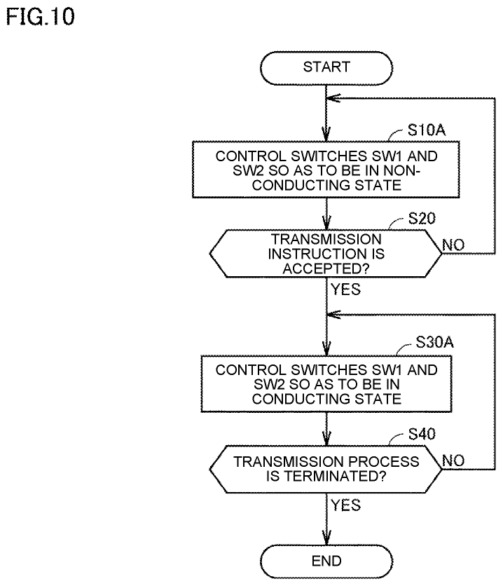

FIG. 10 is a diagram illustrating a flowchart of a process performed in the control circuit 120 in the second embodiment. The flowchart in FIG. 10 differs from the flowchart in FIG. 7 in that Steps S10 and S30 are replaced with Steps S10A and S30A, respectively.

In Step S10A, the control circuit 120 of the second embodiment controls the switch SW2, in addition to the switch SW1, so as to be in the non-conducting state (Step S10A). In Step S30A, the control circuit 120 of the second embodiment controls the switches SW1 and SW2 so as to be in the conducting state (Step S30A). Accordingly, in the radio frequency module 100A of the second embodiment, it is possible to suppress input of the transmission signal into the reception circuit with more reliability due to the LC parallel resonator to further improve the isolation characteristics between the transmission and reception circuits.

### Third Embodiment

In the second embodiment, the configuration including the switches SW1 and SW2 and the capacitors C1 and C2 is described. In a third embodiment, a configuration only including the switch SW2 and the capacitor C2 will be described. Description of the components duplicated with those in the first and second embodiments is not repeated in the third embodiment.

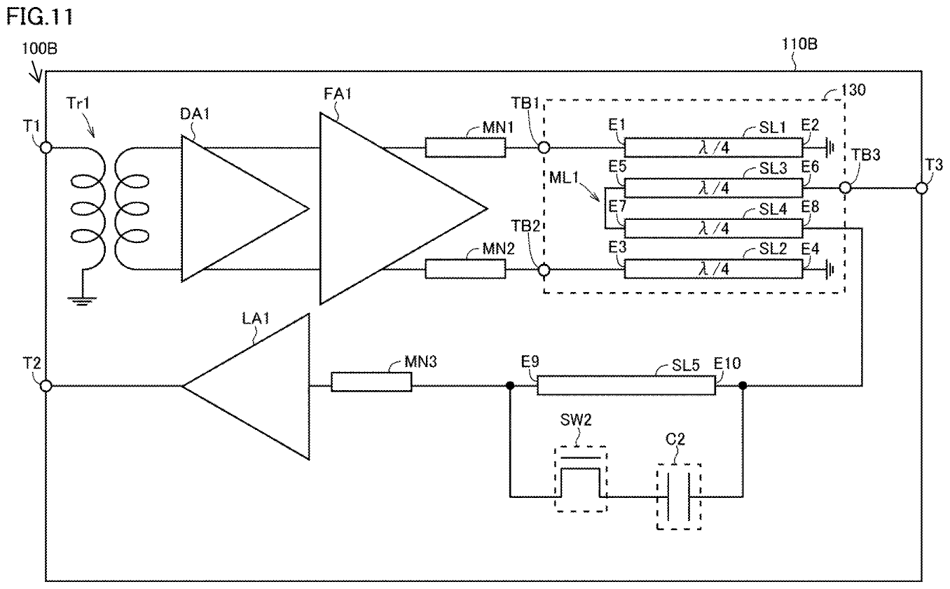

FIG. 11 is a circuit diagram illustrating a detailed configuration of a power amplifier 110B in the third embodiment. In a radio frequency module 100B in the third embodiment, the switch SW2 and the capacitor C2, which are connected in parallel to the line SL5, are arranged, as in the second embodiment, but the shunt path described in the first embodiment is not provided.

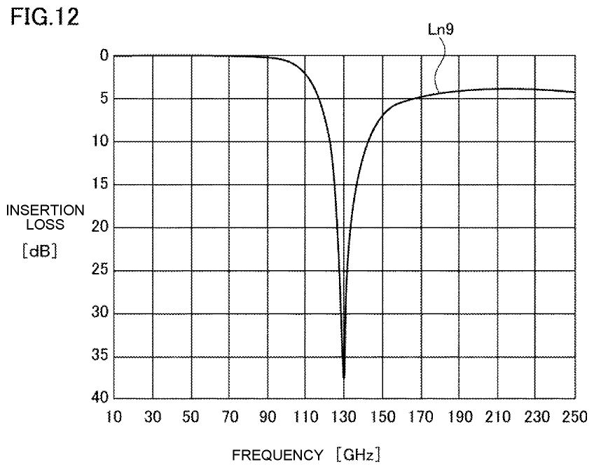

FIG. 12 is a graph indicating the insertion loss of the LC parallel resonant circuit composed of the capacitor C2 and the line SL5 in the third embodiment. A line Ln9 indicates the insertion loss of the LC parallel resonant circuit in the third embodiment.

As illustrated in FIG. 12, in the LC parallel resonant circuit in the third embodiment, the inductance of the line SL5 and the capacitance value of the capacitor C2 are set so that an attenuation pole is generated near 130 GHz. Accordingly, the transmission signal passing through the main line ML1 illustrated in FIG. 11 is inhibited from being supplied to the input terminal of the low-noise amplifier LA1 due to the LC parallel resonant circuit. In other words, also in the third embodiment, the isolation between the power amplifier FA1 and the low-noise amplifier LA1 is ensured due to the LC parallel resonant circuit composed of the capacitor C2 and the line SL5.

### Modification

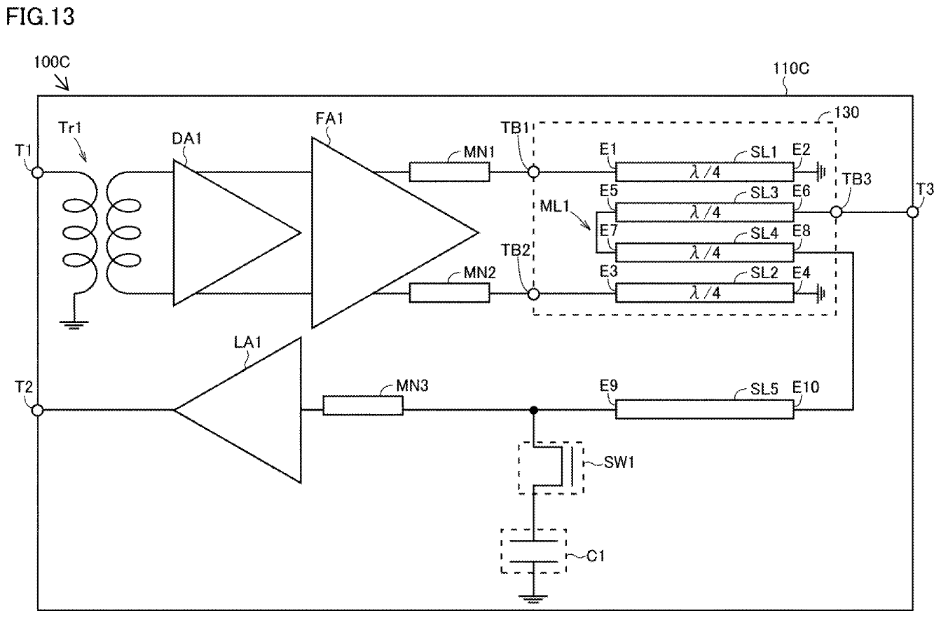

FIG. 13 is a circuit diagram illustrating a detailed configuration of a power amplifier 110C in a modification. In a radio frequency module 100C of the modification, the connection order of the capacitor C1 and the switch SW1 is reversed with respect to that in the first embodiment. In other words, in the modification, the capacitor C1 is provided between the switch SW1 and the ground. “Connection” in the present description includes both direct connection and indirect connection. More specifically, the direct connection is the connection between the capacitor C1 and the switch SW1 in FIG. 2. The indirect connection is the connection between the line SL5 and the low-noise amplifier LA1 in FIG. 2. The line SL5 is indirectly connected to the low-noise amplifier LA1 via the matching circuit MN3. “Terminal” in the present description means an element with which two components are connected and, for example, includes a line and a bump. In the present description, the “terminal” includes a boundary between two components when the two components are directly connected to each other. For example, as illustrated in FIG. 5, the line SL4 and the line SL5 are composed of the same wiring pattern Pt2. In the present description, the boundary between the portion functioning as the line SL4 in the wiring pattern Pt2 and the portion functioning as the line SL5 in the wiring pattern Pt2 is also called the “terminal”.

In the example in FIG. 5, a step for differentiating the line widths is provided between the end portion E8 of the line SL4 and the end portion E10 of the line SL5. However, in an aspect, the line width of the line SL4 may be the same as that of the line SL5. Also in this case, the boundary between the end portion functioning as the line SL4 and the end portion functioning as the line SL5 is called the “connection terminal TB4” in the present embodiment.

### Additional Note 1

A radio frequency module comprising: a first terminal through which a transmission signal passes; a second terminal through which a reception signal passes; a third terminal through which a transmission signal and a reception signal pass; a converter that outputs a first transmission signal and a second transmission signal having a phase opposite to that of the first transmission signal based on the transmission signal that has passed through the first terminal; a first amplifier that amplifies each of the first transmission signal and the second transmission signal; a second amplifier that amplifies a reception signal to output the amplified reception signal to the second terminal; a first line having one end into which the first transmission signal amplified by the first amplifier is inputted and the other end that is grounded; a second line having one end into which the second transmission signal amplified by the first amplifier is inputted and the other end that is grounded; a third line that has one end connected to the third terminal and that is arranged side by side with the first line; a fourth line that has one end connected to the other end of the third line and that is arranged side by side with the second line; a fifth line having one end connected to the other end of the fourth line and the other end connected to an input terminal of the second amplifier; and a first switch provided between the other end of the fifth line and the ground.

### Additional Note 2

The radio frequency module according to Additional note 1, further comprising: a first capacitor provided between the other end of the fifth line and the first switch.

### Additional Note 3

The radio frequency module according to Additional note 1, further comprising: a first capacitor provided between the first switch and the ground.

### Additional Note 4

The radio frequency module according to Additional note 2 or Additional note 3, wherein, when the first switch is in a conducting state, the first capacitor and the fifth line compose a low pass filter.

### Additional Note 5

The radio frequency module according to any one of Additional note 1 to Additional note 4, further comprising: a second capacitor connected to the fifth line; and a second switch connected to the fifth line, wherein, when the second switch is in a conducting state, the second capacitor and the fifth line compose a parallel resonator.

### Additional Note 6

A communication device including the radio frequency module according to any one of Additional note 1 to Additional note 5, the communication device comprising: an antenna connected to the third terminal.

### Additional Note 7

The communication device according to Additional note 6, further comprising: a signal processing circuit that processes a radio frequency signal passing through the radio frequency module.

### Additional Note 8

A control method used for a radio frequency module, wherein the radio frequency module includes a first terminal through which a transmission signal passes, a second terminal through which a reception signal passes, a third terminal through which a transmission signal and a reception signal pass, a converter that outputs a first transmission signal and a second transmission signal having a phase opposite to that of the first transmission signal based on the transmission signal that has passed through the first terminal, a first amplifier that amplifies each of the first transmission signal and the second transmission signal, a second amplifier that amplifies a reception signal to output the amplified reception signal to the second terminal, a first line having one end into which the first transmission signal amplified by the first amplifier is inputted and the other end that is grounded, a second line having one end into which the second transmission signal amplified by the first amplifier is inputted and the other end that is grounded, a third line that has one end connected to the third terminal and that is arranged side by side with the first line, a fourth line that has one end connected to the other end of the third line and that is arranged side by side with the second line, a fifth line having one end connected to the other end of the fourth line and the other end connected to an input terminal of the second amplifier, and a first switch provided between the other end of the fifth line and the ground, the control method comprising: setting the first switch to a non-conducting state in reception of radio waves; and setting the first switch to a conducting state in transmission of radio waves.

### Additional Note 9

The control method according to Additional note 8, wherein the radio frequency module further includes a second capacitor connected to the fifth line, and a second switch connected to the fifth line, and wherein, when the second switch connected to the fifth line is in the conducting state, the second capacitor and the fifth line compose a parallel resonator, the control method comprising: setting the second switch to the non-conducting state in reception of radio waves; and setting the second switch to the conducting state in transmission of radio waves.

### Additional Note 10

A radio frequency module comprising: a first terminal through which a transmission signal passes; a second terminal through which a reception signal passes; a third terminal through which a transmission signal and a reception signal pass; a converter that outputs a first transmission signal and a second transmission signal having a phase opposite to that of the first transmission signal based on the transmission signal that has passed through the first terminal; a first amplifier that amplifies each of the first transmission signal and the second transmission signal; a second amplifier that amplifies a reception signal to output the amplified reception signal to the second terminal; a first line having one end into which the first transmission signal amplified by the first amplifier is inputted and the other end that is grounded; a second line having one end into which the second transmission signal amplified by the first amplifier is inputted and the other end that is grounded; a third line that has one end connected to the third terminal and that is electromagnetically coupled to the first line; a fourth line that has one end connected to the other end of the third line and that is electromagnetically coupled to the second line; a fifth line having one end connected to the other end of the fourth line and the other end connected to an input terminal of the second amplifier; and a first switch provided between the other end of the fifth line and the ground.

### additional Note 11

A radio frequency module comprising: a first terminal through which a transmission signal passes; a second terminal through which a reception signal passes; a third terminal through which a transmission signal and a reception signal pass; a converter that outputs a first transmission signal and a second transmission signal having a phase opposite to that of the first transmission signal based on the transmission signal that has passed through the first terminal; a first amplifier that amplifies each of the first transmission signal and the second transmission signal; a second amplifier that amplifies a reception signal to output the amplified reception signal to the second terminal; a first line having one end into which the first transmission signal amplified by the first amplifier is inputted and the other end that is grounded; a second line having one end into which the second transmission signal amplified by the first amplifier is inputted and the other end that is grounded; a third line that has one end connected to the third terminal and that is arranged side by side with the first line; a fourth line that has one end connected to the other end of the third line and that is arranged side by side with the second line; a fifth line having one end connected to the other end of the fourth line and the other end connected to an input terminal of the second amplifier; a second capacitor connected to the fifth line; and a second switch connected to the fifth line, wherein, when the second switch connected to the fifth line is in a conducting state, the second capacitor and the fifth line compose a parallel resonator.

The embodiments disclosed here are only examples in all points and should be considered not to be restrictive. The scope of the present disclosure is indicated not by the above description but by the appended claims. Meanings equivalent to the claims and all the modifications within the scope are intended to be included in the present disclosure.
LA1 low-noise amplifier
30 antenna
100, 100A to 100C, 100Z radio frequency module
110, 110A to 110C, 110Z power amplifier
120 control circuit
130 balun
200 power supply circuit
300 signal processing circuit
1000 communication device
C1, C2 capacitor
Cp1 point
DA1 driver amplifier
E1 to E10, H1, H2 end portion
FA1 power amplifier
L1Z inductor
Ln1 to Ln9 line
ML1 main line
MN1 to MN3 matching circuit
Pt1 to Pt3 wiring pattern
SL1 to SL5 line
SW1, SW2, SW1Z, SW2Z switch
Sb1 dielectric substrate
Sf1 main surface
T1 to T3, TB4 connection terminal
TB1, TB2 balanced terminal
TB3 unbalanced terminal
Tr1 transformer

1. A radio frequency module comprising:
a first terminal through which a transmission signal passes;
a second terminal through which a reception signal passes;
a third terminal through which a transmission signal and a reception signal pass;
a converter configured to output a first transmission signal and a second transmission signal having a phase opposite to that of the first transmission signal based on the transmission signal that passed through the first terminal;
a first amplifier configured to amplify each of the first transmission signal and the second transmission signal;
a second amplifier configured to amplify a reception signal to output the amplified reception signal to the second terminal;
a first line having a first end into which the first transmission signal amplified by the first amplifier is inputted, and a second end that is grounded;
a second line having a first end into which the second transmission signal amplified by the first amplifier is inputted, and a second end that is grounded;
a third line that has a first end connected to the third terminal and that is arranged side by side with the first line;
a fourth line that has a first end connected to a second end of the third line and that is arranged side by side with the second line;
a fifth line that has a first end connected to a second end of the fourth line, and a second end connected to an input terminal of the second amplifier; and
a first switch between the second end of the fifth line and ground.

2. The radio frequency module according to claim 1, further comprising:
a first capacitor between the second end of the fifth line and the first switch.

3. The radio frequency module according to claim 1, further comprising:
a first capacitor between the first switch and ground.

4. The radio frequency module according to claim 2, wherein, when the first switch is in a conducting state, the first capacitor and the fifth line compose a low pass filter.

5. The radio frequency module according to claim 1, further comprising:
a second capacitor connected to the fifth line; and
a second switch connected to the fifth line,
wherein, when the second switch is in a conducting state, the second capacitor and the fifth line compose a parallel resonator.

6. A communication device comprising:
the radio frequency module according to claim 1; and
an antenna connected to the third terminal of the radio frequency module.

7. The communication device according to claim 6, further comprising:
a signal processing circuit configured to process a radio frequency signal passing through the radio frequency module.

8. A control method used for a radio frequency module,
wherein the radio frequency module comprises:
a first terminal through which a transmission signal passes,
a second terminal through which a reception signal passes,
a third terminal through which a transmission signal and a reception signal pass,
a converter configured to output a first transmission signal and a second transmission signal having a phase opposite to that of the first transmission signal based on the transmission signal that passed through the first terminal,
a first amplifier configured to amplify each of the first transmission signal and the second transmission signal,
a second amplifier configured to amplify a reception signal to output the amplified reception signal to the second terminal,
a first line having a first end into which the first transmission signal amplified by the first amplifier is inputted, and a second end that is grounded,
a second line having a first end into which the second transmission signal amplified by the first amplifier is inputted, and a second end that is grounded,
a third line that has a first end connected to the third terminal and that is arranged side by side with the first line,
a fourth line that has a first end connected to a second end of the third line and that is arranged side by side with the second line,
a fifth line having a first end connected to a second end of the fourth line, and a second end connected to an input terminal of the second amplifier, and
a first switch between the second end of the fifth line and ground, the control method comprising:
setting the first switch to a non-conducting state during reception of radio waves; and
setting the first switch to a conducting state during transmission of radio waves.

9. The control method according to claim 8,
wherein the radio frequency module further comprises:
a second capacitor connected to the fifth line, and
a second switch connected to the fifth line, and
wherein, when the second switch connected to the fifth line is in the conducting state, the second capacitor and the fifth line compose a parallel resonator, the control method comprising:
setting the second switch to the non-conducting state during reception of radio waves; and
setting the second switch to the conducting state during transmission of radio waves.

10. A radio frequency module comprising:
a first terminal through which a transmission signal passes;
a second terminal through which a reception signal passes;
a third terminal through which a transmission signal and a reception signal pass;
a converter configured to output a first transmission signal and a second transmission signal having a phase opposite to that of the first transmission signal based on the transmission signal that passed through the first terminal;
a first amplifier configured to amplify each of the first transmission signal and the second transmission signal;
a second amplifier configured to amplify a reception signal to output the amplified reception signal to the second terminal;
a first line having a first end into which the first transmission signal amplified by the first amplifier is inputted, and a second end that is grounded;
a second line having a first end into which the second transmission signal amplified by the first amplifier is inputted, and a second end that is grounded;
a third line that has a first end connected to the third terminal and that is electromagnetically coupled to the first line;
a fourth line that has a first end connected to a second end of the third line and that is electromagnetically coupled to the second line;
a fifth line having a first end connected to a second end of the fourth line, and a second end connected to an input terminal of the second amplifier; and
a first switch between the second end of the fifth line and ground.
